(19) United States
(12) Patent Application Publication
(10) Pub. No.: US 2020/0066764 A1
(43) Pub. Date: Feb. 27, 2020

(54) DISPLAY DEVICE STRUCTURE AND FLEXIBLE DISPLAY HAVING SAME

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Zhonglin Cao, Beijing (CN); Shan Gao, Beijing (CN); Ting Li, Beijing (CN)

(21) Appl. No.: 16/349,913

(22) PCT Filed: Apr. 12, 2018
(86) PCT No.: PCT/CN2018/082752

§ 371 Date: May 14, 2019

(30) Foreign Application Priority Data
Aug. 2, 2017 (CN) 201710652310.5

(51) Int. Cl. H01L 27/12

(52) U.S. Cl. CPC H01L 27/1248; H01L 27/1244

(57) ABSTRACT

The present disclosure provides a display device structure and a flexible display having the same. The display device structure includes an insulating layer. The insulating has a first surface and a second surface oppositely disposed. The second surface is provided with a lower-layer wiring. The display device structure includes a plurality of accommodating structures disposed at a portion of the insulating layer which does not correspond to the lower-layer wiring. The display device structure includes a post disposed on at least one of the plurality of accommodating structures.

### CROSS-REFERENCE TO RELATED APPLICATIONS

The present application is based on International Application No. PCT/CN2018/082752, filed on Apr. 12, 2018, which is based upon and claims priority to Chinese Application No. 201710652310.5, filed on Aug. 2, 2017, the entire disclosure of which is hereby incorporated by reference.

### TECHNICAL FIELD

The present disclosure relates to the field of semiconductor display technology, and in particular to a display device structure and a flexible display having the same.

### BACKGROUND

Referring to FIGS. 1 and 2, there are shown a schematic structural view and a cross-sectional view, respectively, of an insulating layer of an existing flexible display. As shown in FIG. 1 and FIG. 2, the insulating layer 101 of the existing flexible display is configured to have a large block structure, and the large block structure of the insulating layer 101 is subjected to a larger stress when bent, which easily causes the insulating region of an upper-layer metal wire and a lower-layer metal wire 102 to be broken, eliminate the insulating effect of the insulating layer 101, and lead to a problem of poor display.

### SUMMARY

One technical problem to be solved by the present disclosure is how to provide a display device structure in which an insulating layer is less likely to be broken.

Another technical problem to be solved by the present disclosure is how to provide a flexible display having the above-described display device structure.

The additional aspects and advantages of the present disclosure will be set forth in part in the following description, and will be apparent in part from the following description, or can be learned by practice of the present disclosure.

To achieve the above objective, the present disclosure applies the following technical solutions. According to an aspect of the present disclosure, there is provided a display device structure. The display device structure includes an insulating layer having a first surface and a second surface oppositely disposed. The second surface is provided with a lower-layer wiring. The display device structure includes a plurality of accommodating structures disposed at a portion of the insulating layer which does not correspond to the lower-layer wiring. The display device structure includes a post disposed on at least one of the plurality of accommodating structures.

According to one of arrangements of the present disclosure, the accommodating structure includes a through hole formed at the insulating layer and penetrating through the first surface and the second surface of the insulating layer.

According to one of arrangements of the present disclosure, a cross section of the through hole is circular, elliptical or regular polygonal. A longitudinal section of the through hole is inverted trapezoidal or rectangular.

According to one of arrangements of the present disclosure, a portion of the post protrudes from the first surface of the insulating layer when the post is provided in the through hole.

According to one of arrangements of the present disclosure, a cross section of the portion of the post protruding from the first surface of the insulating layer is circular, elliptical or regular polygonal.

According to one of arrangements of the present disclosure, a longitudinal section of the portion of the post protruding from the first surface of the insulating layer is trapezoidal or rectangular.

According to one of arrangements of the present disclosure, at least one through hole is provided with the post, and the post partially protrudes from the first surface of the insulating layer.

According to one of arrangements of the present disclosure, a cross section of the portion of the post protruding from the first surface of the insulating layer is circular, elliptical or regular polygonal.

According to one of arrangements of the present disclosure, a longitudinal section of the portion of the post protruding from the first surface of the insulating layer is trapezoidal or rectangular.

According to one of arrangements of the present disclosure, each through hole is provided with one post.

According to one of arrangements of the present disclosure, the accommodating structure includes a groove; the groove is formed to a first surface or a second surface of the insulating layer.

According to one of arrangements of the present disclosure, a convex structure is formed at a position of the first surface of the insulating layer corresponding to the groove when the groove is formed to the second surface of the insulating layer.

According to one of arrangements of the present disclosure, at least one groove is provided with the post.

According to one of arrangements of the present disclosure, the post is completely received in the groove without protruding from the second surface.

According to one of arrangements of the present disclosure, a convex structure is formed at a position of the second surface of the insulating layer corresponding to the groove when the groove is formed to the first surface of the insulating layer.

According to one of arrangements of the present disclosure, a material of the post is the same as a material of the lower-layer wiring.

According to one of arrangements of the present disclosure, an upper-layer wiring is disposed at the first surface of the insulating layer, a material of the post is the same as a material of the upper-layer wiring.

According to one of arrangements of the present disclosure, a material of the post and the lower-layer wiring is metal.

According to another aspect of the present disclosure, there is provided a flexible display. The flexible display includes the display device structure described in the above arrangements.

As such, the display device structure and the flexible display having the same proposed by the present disclosure disperse a stress subjected by the insulating layer by using a plurality of accommodating structures formed in the insulating layer. Moreover, the post is provided in the accommodating structure to further enhance the structural strength. With the above design, the present disclosure prevents the insulating layer from being easily broken, or the breaking will concentrate on the portion of the insulating layer where the accommodating structure is formed even if the breaking occurs, e.g., keeping away from the position of the insulating layer corresponding to the wiring, so that the insulation layer of the wiring is effectively protected, and a problem of poor display is avoided.

### BRIEF DESCRIPTION OF THE DRAWINGS

FIG. 1 is a schematic structural view of an insulating layer of an existing flexible display;

FIG. 2 is a cross-sectional view of the insulating layer of the flexible display shown in FIG. 1;

FIG. 3 is a schematic structural view of an insulating layer of a display device structure according to an exemplary arrangement;

FIG. 4 is a cross-sectional view showing the insulating layer of the display device structure shown in FIG. 3;

FIG. 5 is a schematic structural view of an insulating layer of a display device structure according to another exemplary arrangement.

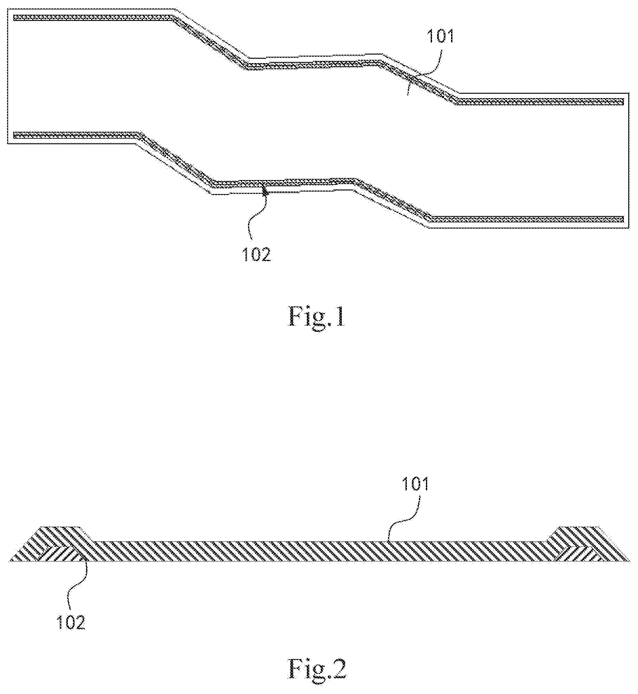

### DETAILED DESCRIPTION

The same reference numbers in the drawings denote the same or similar structures, and thus the detailed description thereof will be omitted. Example arrangements will now be described more fully with reference to the accompanying drawings. However, the example arrangements can be embodied in a variety of forms and should not be construed as being limited to arrangements set forth herein. Rather, these arrangements are provided so that the present disclosure will be thorough and complete, and the concept thereof will be fully conveyed to the person skilled in the art.

### First Arrangement of Display Device Structure

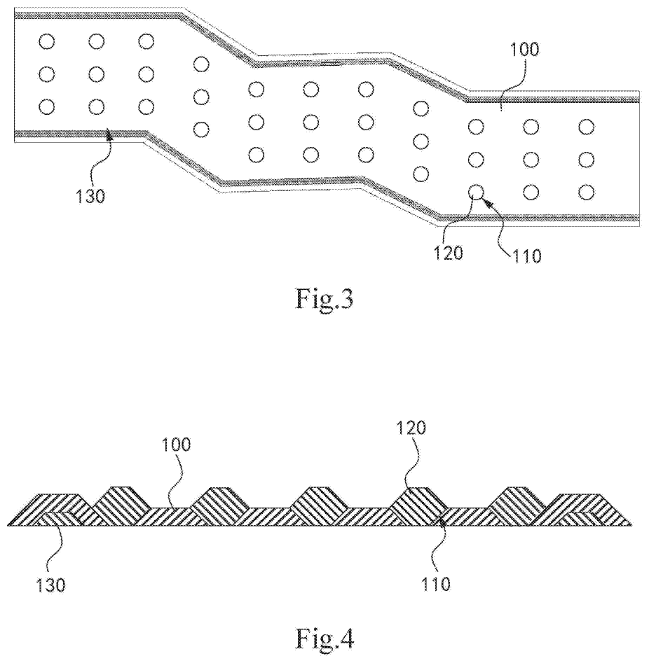

Referring to FIG. 3, a schematic structural view of an implementation of a display device structure capable of embodying the principle of the present disclosure is representatively shown. In the exemplary arrangement, a design about the insulating layer 100 proposed by the present disclosure is exemplified by a display device structure applied to a flexible display. It will be readily understood by the person skilled in the art that various modifications, additions, substitutions, deletions or other changes are made to the specific arrangements described below in order to apply the design of the display device structure to other types of flexible products or displays. These changes are still within the scope of the principles of the display device structure proposed by the present disclosure.

As shown in FIG. 3, in the present arrangement, the display device structure proposed by the present disclosure at least includes an insulating layer 100 and a lower-layer wiring 130 disposed below the insulating layer. Referring to and in combination with FIG. 4, a cross-sectional view of a display device structure capable of embodying the principles of the present disclosure is representatively shown. The structure, connection mode and functional relationship of various main components of the display device structure proposed by the present disclosure will be described in detail below with reference to the above drawings.

As shown in FIG. 3 and FIG. 4, in the present arrangement, the insulating layer has a first surface S1 and a second surface S2 oppositely disposed. A portion of the insulating layer 100 which does not correspond to the lower-layer wiring 130 is formed with a plurality of through holes 110, and each of the through holes 110 is formed at the insulating layer 100 and penetrates through the first surface S1 and the second surface S2 of the insulating layer 100. Moreover, a post 120 is disposed at least one of a plurality of the through holes 110. In the present arrangement, one post 120 is provided in each of the through holes 110. In the present arrangement, a material of the post 120 is the same as a material of the lower-layer wiring 130, i.e., metal, so as to be manufactured and formed in the same process. For example, in case of that the lower-layer wiring 130 is formed by conventional semiconductor film formation, photolithography, development, and etching methods, the insulating layer 110 provided with through holes 110 may be formed in the same method, and the post 120 is formed in each of the through holes 110. In other arrangements, the material of the post 120 is not limited to the same material as that of the lower-layer wiring 130. The post 120 may also be made of other materials, such as the same material as that of the upper-layer wiring, which will not be limited to this arrangement.

Further, as shown in FIG. 3, in the present arrangement, a cross section of the through hole 110 is preferably circular. In other arrangements, the cross section of the through hole 110 may also be in other shapes such as a ellipse or a regular polygon, and is not limited to the arrangement. Further, as shown in FIG. 4, in the present arrangement, a longitudinal section of the through hole 110 is preferably an inverted trapezoid. In other arrangements, the longitudinal section of the through hole 110 may be in other shapes such as a rectangle, and is not limited to the arrangement.

As shown in FIG. 4, in the present arrangement, a top portion of the post 120 protrudes from the first surface S1 of the insulating layer 100 when the post 120 is provided in the through hole 110. In addition, the post 120 substantially fills all of hole cavities of the through holes 110.

Further, as shown in FIG. 3, in the present arrangement, the cross section of the portion of the post 120 protruding from the first surface S1 of the insulating layer 100 is preferably circular. In other arrangements, the cross section of the portion of the post 120 protruding from the first surface S1 of the insulating layer 100 may also be other shapes such as an ellipse or a regular polygon. It should be noted that the cross section of the through hole 110 and the portion of the post 120 protruding from the first surface S1 of the insulating layer 100 are both designed in a circular shape in the present arrangement, however, it does not mean that the cross-sections of the above-mentioned two structures are designed to be in the same shape in other arrangements of the present disclosure. For example, when the cross section of the through hole 110 is circular, the cross section of the portion of the post 120 protruding from the first surface S1 of the insulating layer 100 may also be in other shapes such as an ellipse or a regular polygon, which will not be limited thereto.

Further, as shown in FIG. 4, in the present arrangement, a longitudinal section of the portion of the post 120 protruding from the first surface S1 of the insulating layer 100 is trapezoidal. That is, in the present arrangement, the longitudinal sections of the portion in which the post 120 is accommodated in the through hole 110 and the portion protruding from the first surface S1 of the insulating layer 100 (the portion exposed to the through hole 110) are in substantially symmetrical shapes. It should be noted that the longitudinal sections of the portion in which the post 120 is accommodated in the through hole 110 and the portion protruding from the first surface S1 of the insulating layer 100 in the present arrangement are designed to be in substantially symmetrical shapes, however, it is not indicated in other arrangements of the present disclosure that the longitudinal sections of two above-mentioned portions of the post 120 is designed to be symmetrical. For example, when the longitudinal section of the through hole 110 is rectangular, i.e., when the longitudinal section of the portion of the post 120 accommodated in the through hole 110 is rectangular, the longitudinal section of the portion of the post 120 protruding from the first surface S1 of the insulating layer 100 may also preferably be trapezoidal. Thus, the trapezoidal design of the present arrangement is to enable the portion of the post 120 protruding from the first surface S1 of the insulating layer 100 to form a ramp-like structure, so that the bending stress of the insulating layer 100 of the display device structure is further alleviated and breaking of the insulating layer 100 is prevented.

In addition, the structures shown in the drawings are merely schematic forms for easy understanding and description, and all details of the actual arrangement of the present disclosure are not fully exhibited. For example, as shown in FIG. 3, the through holes 110 are uniformly distributed at the insulating layer 100. However, in the actual arrangement process, the plurality of through holes 110 formed in the insulating layer 100 are preferably distributed in an irregular manner, thus further avoiding concentration of stress and further avoiding the problem of breaking of the insulating layer 100.

### Second Arrangement of Display Device Structure

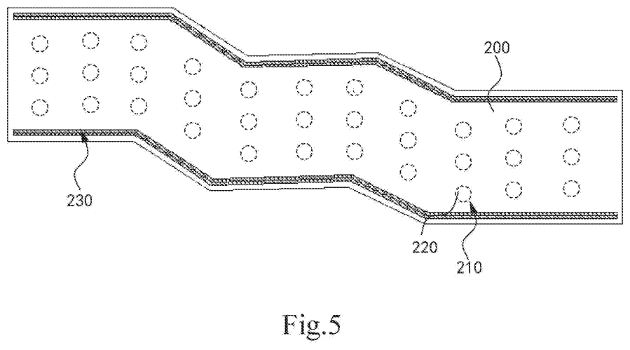

Referring to FIG. 5, a schematic structural view of another arrangement of a display device structure capable of embodying the principles of the present disclosure is representatively shown. The design of the insulating layer 200 of the display device structure proposed in the present arrangement is substantially the same as the first arrangement of the present disclosure, however, the main differences are:

As shown in FIG. 5, in the present arrangement, the second surface S2 of the portion of the insulating layer 200 that does not correspond to the lower-layer wiring 230 is provided with a plurality of grooves 210, i.e., openings of the grooves 210 are formed at the second surface S2 of the insulating layer 200. Also, a post 220 is disposed in at least one of a plurality of the grooves 210. In the present arrangement, one post 220 is accommodated in each of the grooves 210. The post 220 is completely accommodated in the groove 210, i.e., the post 220 is not exposed to the notch (the second surface S2 of the insulating layer 200), such as the second surface S2 of the post 220 is flush with the second surface S2 of the insulating layer 200, or recessed relative to the second surface S2. Further, a plurality of convex structures are respectively raised and formed at positions of the first surface S1 of the insulating layer 200 corresponding to the plurality of grooves 210 (posts 220). On the basis of the design about “trapezoid” in the first arrangement, in the present arrangement, the longitudinal sections of the groove 210 and the post 220 are substantially trapezoidal, i.e., the longitudinal section of the convex structure formed on the first surface S1 of the insulating layer 200 is trapezoidal, so that the ramp-like structure in the first arrangement is formed, thus further alleviating the bending stress of the insulating layer 200 of the display device structure, and preventing the insulating layer 200 from being broken.

### Third Arrangement of Display Device Structure

A third arrangement of the display device structure proposed by the present disclosure will be described below. The design of the insulating layer of the display device structure proposed in the present arrangement is substantially the same as the first arrangement and the second arrangement of the present disclosure, however, the main differences are:

In the arrangement, the first surface S1 of the insulating layer is provided with a plurality of grooves, i.e., openings of the grooves are formed at the first surface S1 of the insulating layer. Also, a post is accommodated in each of the grooves. In other words, the structure of the insulating layer proposed in the present arrangement may be approximately understood as that a bottom opening of the through hole in the first arrangement is closed, and the remaining structures are substantially the same.

It should be noted herein that the display device structure illustrated in the drawings and described in this specification are merely a few examples of the many types of display device structures that can employ the principles of the present disclosure. It should be clearly understood that the principles of the present disclosure are limited to any detail of the display device structure or any component of the display device structure shown in the drawings or described in the specification.

For example, the structure of the through hole or the groove may be replaced by other accommodating structures, i.e., a plurality of accommodating structures are formed at the insulating layer for accommodating posts. Also, for example, in each of the accommodating structures, it is not necessary to provide a post. That is, by designing the accommodating structure at the insulating layer, it is possible to change the stress distribution of the existing insulating layer and reduce the possible design purpose of breaking. Of course, provision of the post can further strengthen the structural strength and improve the stress distribution, so that a post may be disposed on at least one of the plurality of accommodating structures.

### Arrangement of Flexible Display

The present disclosure also provides a flexible display. In an exemplary arrangement of the flexible display, the flexible display includes the display device structure proposed by the present disclosure.

In summary, the display device structure and the flexible display having the same proposed by the present disclosure disperse the stress on the insulating layer by using a plurality of accommodating structures formed in the insulating layer. Moreover, the structural strength is further enhanced by providing the post in the accommodating structure. With the above design, the present disclosure prevents the insulating layer from being easily broken, or the breaking will concentrate on the portion of the insulating layer where the accommodating structure is formed even if the breaking occurs, i.e., keeping away from the position of the insulating layer corresponding to the wiring, so that the insulation layer of the wiring is effectively protected, and a problem of poor display is avoided.

The present disclosure has been described with reference to a few exemplary arrangements, however, it should be understood that the terms used are illustrative and exemplary, but not restrictive. The present disclosure may be embodied in a variety of forms without departing from the spirit or scope of the present disclosure, so it should be understood that the above-mentioned arrangements are not limited to any previous details. Rather, it should be widely interpreted within the spirit and scope defined by the appended claims. Therefore, all changes and modifications within the scope of the claims or the equivalents thereof are intended to be covered by the appended claims.

1. A display device structure, comprising:
an insulating layer having a first surface and a second surface oppositely disposed to each other, the second surface being provided with a lower-layer wiring;
a plurality of accommodating structures disposed at a portion of the insulating layer which does not correspond to the lower-layer wiring; and
a post disposed over at least one of the plurality of accommodating structures.

2. The display device structure according to claim 1, wherein
the plurality of accommodating structures each comprises a through hole;
the through hole is formed at the insulating layer and penetrates through the first surface and the second surface of the insulating layer.

3. The display device structure according to claim 2, wherein
a cross section of the through hole is at least one of circular, elliptical or regular polygonal.

4. The display device structure according to claim 2, wherein
a longitudinal section of the through hole is either inverted trapezoidal or rectangular.

5. The display device structure according to claim 2, wherein
the through hole is provided with the post, and the post partially protrudes from the first surface of the insulating layer.

6. The display device structure according to claim 5, wherein
a cross section of the portion of the post protruding from the first surface of the insulating layer is at least one of circular, elliptical or regular polygonal.

7. The display device structure according to claim 5, wherein
a longitudinal section of the portion of the post protruding from the first surface of the insulating layer is either trapezoidal or rectangular.

8. The display device structure according to claim 1, wherein
the plurality of accommodating structures each includes a groove;
the groove is formed to the first surface or the second surface of the insulating layer.

9. The display device structure according to claim 8, wherein
a convex structure is formed at a position of the first surface of the insulating layer corresponding to the groove when the groove is formed to the second surface of the insulating layer.

10. The display device structure according to claim 1, wherein
a material of the post is the same as a material of the lower-layer wiring.

11. The display device structure according to claim 1, wherein
an upper-layer wiring is disposed at the first surface of the insulating layer, a material of the post is the same as a material of the upper-layer wiring.

12. A flexible display, comprising a display device structure,
wherein the display device structure comprises:
an insulating layer having a first surface and a second surface oppositely disposed, the second surface being provided with a lower-layer wiring;
a plurality of accommodating structures disposed at a portion of the insulating layer which does not correspond to the lower-layer wiring; and
a post disposed on at least one of the plurality of the accommodating structures.

13. The display device structure according to claim 5, wherein the through hole is provided with one post.

14. The display device structure according to claim 9, wherein the groove is provided with the post.

15. The display device structure according to claim 14, wherein the post is completely received in the groove without protruding from the second surface.

16. The display device structure according to claim 8, wherein
a convex structure is formed at a position of the second surface of the insulating layer corresponding to the groove when the groove is formed to the first surface of the insulating layer.

17. The display device structure according to claim 1, wherein
a material of the post and the lower-layer wiring is metal.
